(19) United States
(12) Patent Application Publication
(10) Pub. No.: US 2008/0087901 A1
(43) Pub. Date: Apr. 17, 2008

(54) OPTICAL COUPLING TYPE SEMICONDUCTOR DEVICE, METHOD FOR PRODUCING OPTICAL COUPLING TYPE SEMICONDUCTOR DEVICE, AND ELECTRONIC DEVICE

(76) Inventor: Naoki SATA, Nara (JP)

Correspondence Address: BIRCH STEWART KOLASCH & BIRCH, PO BOX 747, FALLS CHURCH, VA, 22040-0747, US

(21) Appl. No.: 11/860,403

(22) Filed: Sep. 24, 2007

(30) Foreign Application Priority Data
Oct. 16, 2006 (JP) 2006-281552

(51) Int. Cl. H01L 31/12; H01L 33/00

(52) U.S. Cl. 257/82; 257/E33.076; 257/E31.096

(57) ABSTRACT

In an embodiment of an optical coupling type semiconductor device according to the present invention, in an optical coupling type semiconductor device that is provided with lead frames on which a light emitting element and a light receiving element have been respectively separately mounted and a resin sealing member that seals the light emitting element and the light receiving element, a plurality of protrusion portions are formed on the lead frames.

This application claims priority under 35 U.S.C. §119 (a) on Patent Application No. 2006-281552 filed in Japan on Oct. 16, 2006, the entire contents of which are hereby incorporated by reference.

### BACKGROUND OF THE INVENTION

1. Field of Invention

The present invention relates to an optical coupling type semiconductor device that is provided with lead frames on which a light emitting element and a light receiving element are respectively separately mounted and a resin sealing member that seals the light emitting element and the light receiving element, and further relates to a method for producing the optical coupling type semiconductor device and an electronic device on which the optical coupling type semiconductor device has been mounted.

### DESCRIPTION OF RELATED ART

Recent trends in semiconductor devices (such as an optical coupling type semiconductor device, which is a semiconductor device with a double mold structure) indicate that increases in the current capacity as well as package size reduction have been desired.

FIG. 8 is a see-through side view that shows the schematic configuration of a conventional semiconductor device with a double mold structure. FIG. 9 is a flow chart that illustrates general production steps of the conventional semiconductor device shown in FIG. 8.

Conventional semiconductors with a double mold structure are applied, for example, to optical coupling type semiconductor devices. In other words, FIG. 8 shows an optical coupling type semiconductor device as a semiconductor device. Also, FIG. 9 shows a flow chart of steps for producing the optical coupling type semiconductor device shown in FIG. 8.

As shown in FIG. 9, the optical coupling type semiconductor device is formed by performing processing in a die bonding step, a wire bonding step, a molding step, and others.

First, a light emitting element 101 and a light receiving element 102 are respectively die-bonded to separate lead frames (light emitting side lead frame 103 and light receiving side lead frame 104) (die bonding step), and after wire bonding each of them with a wire (light emitting side wire 105 and light receiving side wire 106) such as gold wire (wire bonding step), a silicone resin 107 is applied as a pre-coat to the light emitting element 101 (pre-coating step).

Subsequently, the light emitting element 101 and the light receiving element 102 are disposed so that they optically face each other by spot welding the light emitting side lead frame 103 and the light receiving side lead frame 104 (welding step), by setting them to a loading frame (not shown), or by using another method.

Then, a primary resin sealing member 108 is formed by performing a primary molding with translucent resin so that the light emitting element 101 and the light receiving element 102 that have been optically positioned are enclosed (primary molding step). After deburring resin burrs formed in the primary molding, a secondary resin sealing member 109 is formed by performing a secondary molding with light intercepting resin so that the outer circumference of the primary resin sealing member 108 is covered (secondary molding step).

Subsequently, plating treatment (external plating step), tie bar cutting, lead bending (forming step) and others are performed on external terminal portions 103T and 104T of the light emitting side lead frame 103 and the light receiving side lead frame 104, and, after performing an electrical property inspection (testing step) and an appearance inspection (appearance inspection step), packaging (packaging step) and shipping are performed.

Such a semiconductor device as described above has limited heat dissipation properties as a stand-alone optical coupling type semiconductor device. For example, when the package size is decreased while keeping the conventional current capacity or when the current capacity is increased while keeping the conventional package size, the temperature rise in the optical coupling type semiconductor device becomes excessive and causes deterioration of the light emitting element 101 or the light receiving element 102, which sometimes leads to breakage.

Thus, in the conventional semiconductor devices, when the current capacity exceeds a certain level, heat dissipation properties need to be improved by increasing the size of the package body, by installing a heat dissipation member to the outside of the secondary resin sealing member 109, or by using another method.

For example, in JP H7-130934A (hereinafter referred to as “Patent Document 1”), JP H9-213865A (hereinafter referred to as “Patent Document 2”), and JP H7-235689A (hereinafter referred to as “Patent Document 3”), technology for improving heat dissipation properties by installing a heat sink or the like to a semiconductor device has been disclosed.

In a semiconductor device disclosed in Patent Document 1, a ceramic substrate, in which a concavity and protrusion are formed on the back face of a pad portion for mounting a semiconductor element, is connected with a lead frame, and a semiconductor element is mounted on the pad portion of the ceramic substrate. In other words, heat dissipation properties are improved by mounting the semiconductor element onto the lead frame to which the ceramic substrate, which has a good thermal conduction, has been installed, and heat dissipation properties are further improved by increasing the surface area by providing the ceramic substrate with the concavity and protrusion.

A semiconductor device disclosed in Patent Document 2 has a structure that includes a lead frame provided with a tab for mounting a semiconductor element and a tab suspension lead for supporting the tab as well as a heat dissipation member connected to the tab suspension lead for dissipating the heat generated by the semiconductor element to outside. In other words, heat dissipation properties are improved by dissipating the heat generated by the semiconductor element to outside with the heat dissipation member installed to the tab suspension lead.

A semiconductor device disclosed in Patent Document 3 is an optical coupling type semiconductor device with a double mold structure, and has a structure in which a secondary side lead frame has a light emitting element, a light receiving element, and a power control semiconductor element mounted thereon, and a primary side lead frame is provided with a reflection portion and a heat dissipation portion. In other words, the heat generated by the power control semiconductor element is dissipated to outside through a secondary resin sealing member formed with light intercepting resin.

However, the semiconductor devices disclosed in the above-mentioned Patent Document 1 and Patent Document 2 do not relate to a double mold structure and their application to optical coupling type semiconductor devices has been difficult. For example, if a heat dissipation member is installed to a tab suspension lead of a lead frame by simply applying the technology disclosed in Patent Document 2, a light emitting element and a light receiving element are connected with each other through the heat dissipation member, causing a short circuit between the light emitting element and the light receiving element.

As a solution to the problem, a method is conceivable in which an insulating resin or the like is sandwiched at the portion to which the heat dissipation member is installed, but in this case, standards on air clearance, creepage distance for insulation, and others stipulated by public bodies, such as the Japanese Electrical Appliance and Material Safety Law and overseas safety standards, cannot be satisfied. In other words, it has been difficult, without undermining safety, to improve heat dissipation properties by installing a heat dissipation member in a state in which insulation is secured.

Also, in an optical coupling type semiconductor device disclosed in Patent Document 3, since the reflection portion needs to be disposed so as to correspond to the light emitting element and the light receiving element, and the light dissipation portion needs to be disposed so as to correspond to the power control semiconductor element, it has been difficult to position the light emitting element, the light receiving element, and the power control semiconductor element.

As mentioned above, optical coupling type semiconductor devices have had a problem in that their size cannot be reduced because it is difficult to install a heat dissipation portion and thus there are limitations in their heat dissipation properties In other words, it has been difficult to reduce the size of optical coupling type semiconductor devices when heat dissipation properties need to be secured.

### SUMMARY OF THE INVENTION

The present invention was made in view of the above-described circumstances, and it is an object thereof to provide a small-sized optical coupling type semiconductor device with good heat dissipation properties, a method for producing the optical coupling type semiconductor device, and an electronic device on which the optical coupling type semiconductor device has been mounted.

An optical coupling type semiconductor device according to the present invention is an optical coupling type semiconductor device that is provided with lead frames on which a light emitting element and a light receiving element have been respectively separately mounted and a resin sealing member that seals the light emitting element and the light receiving element, in which a plurality of protrusion portions are formed on the lead frames.

This configuration increases the surface area of the lead frames, and can improve heat dissipation properties of the optical coupling type semiconductor device. In other words, since heat generation during power on is mitigated, when the current capacity is kept the same, an optical coupling type semiconductor device smaller than a conventional optical coupling type semiconductor device can be achieved without undermining safety. Also, when the size of the resin sealing member is kept the same, an optical coupling type semiconductor device with a current capacity larger than that of a conventional optical coupling type semiconductor device can be achieved without undermining safety.

In addition, in an optical coupling type semiconductor device according to the present invention, the protrusion portions may be formed on led-out portions of the lead frames that are led out from side faces of the resin sealing member.

This configuration makes it possible to temporarily secure to a mounting substrate with the protrusion portions when mounting to the substrate.

Also, in an optical coupling type semiconductor device according to the present invention, the protrusion portions may be formed on a face opposite to a mounting face on which the light emitting element or the light receiving element of header portions of the lead frames, having been sealed with the resin sealing member, has been mounted.

This configuration makes it possible to mount a substrate in the same way as conventional substrate mounting since the protrusion portions exist only inside of the resin sealing member when the protrusion portions are formed only on the header portions.

Also, since the surface area of the lead frames increases when the protrusion portions are formed on the header portions as well as on the led-out portions, heat dissipation properties of the optical coupling type semiconductor device can be further improved. In other words, because heat generation during power on is further mitigated, a small-sized optical coupling type semiconductor device with a current capacity larger than that of a conventional optical coupling type semiconductor device can be achieved certainly without undermining safety.

Also, in an optical coupling type semiconductor device according to the present invention, a configuration may be adopted in which the resin sealing member is composed of a primary resin sealing member that covers the light emitting element and the light receiving element and a secondary resin sealing member that covers an outer circumference of the primary resin sealing member, and bottom faces of the protrusion portions are in contact with the outer circumference face of the primary resin sealing member.

Since this configuration shortens the distance between the top faces of the protrusion portions and the outer circumference face of the secondary resin sealing member, heat dissipation properties are further improved.

Also, in an optical coupling type semiconductor device according to the present invention, a configuration may be adopted in which the resin sealing member is composed of a primary resin sealing member that covers the light emitting element and the light receiving element and a secondary resin sealing member that covers an outer circumference of the primary resin sealing member, and the mounting faces of the header portions are in contact with the outer circumference face of the primary resin sealing member.

Since this configuration further shortens the distance between the top faces of the protrusion portions and the outer circumference face of the secondary resin sealing member, heat dissipation properties are further improved.

Also, in an optical coupling type semiconductor device according to the present invention, top faces of the protrusion portions may be in contact with the outer circumference face of the secondary resin sealing member.

Since, in this configuration, the top faces of the protrusion portions are exposed to the outside of the secondary resin sealing member, heat dissipation properties are further improved.

Also, in an optical coupling type semiconductor device according to the present invention, top faces of the protrusion portions may protrude from the outer circumference face of the secondary resin sealing member.

Since, in this configuration, the top faces of the protrusion portions protrude from the secondary resin sealing member, heat dissipation properties are further improved.

Also, a method for producing an optical coupling type semiconductor device according to the present invention is a method for producing an optical coupling type semiconductor device that includes a step of mounting a light emitting element and a light receiving element to respective separate lead frames and a step of sealing the light emitting element and the light receiving element with resin, the method for producing the optical coupling type semiconductor device provided with a step of forming a plurality of protrusion portions on the lead frames.

This configuration increases the surface area of the lead frames, and makes it possible to easily produce an optical coupling type semiconductor device with good heat dissipation properties in an ordinary way. That is, since an optical coupling type semiconductor device with mitigated heat generation during power on can be produced, it is possible to produce a small-sized optical coupling type semiconductor device with a current capacity larger than that of a conventional optical coupling type semiconductor device.

Also, the present invention provides an electronic device on which an optical coupling type semiconductor device according to the present invention has been mounted.

This configuration makes it possible to achieve size reduction of the electronic device without undermining safety.

### BRIEF DESCRIPTION OF THE DRAWINGS

FIG. 1 is a see-through side view that shows the schematic configuration of an optical coupling type semiconductor device according to Embodiment 1 of the present invention.

FIG. 2 is a see-through side view that shows the schematic configuration of an optical coupling type semiconductor device according to Embodiment 2 of the present invention.

FIG. 3 is a see-through side view that shows the schematic configuration of an optical coupling type semiconductor device according to Embodiment 3 of the present invention.

FIG. 4 is a see-through side view that shows the schematic configuration of an optical coupling type semiconductor device according to Embodiment 4 of the present invention.

FIG. 5 is a see-through side view that shows the schematic configuration of an optical coupling type semiconductor device according to Embodiment 5 of the present invention.

FIG. 6 is a see-through side view that shows the schematic configuration of an optical coupling type semiconductor device according to Embodiment 6 of the present invention.

FIG. 7 is a see-through side view that shows the schematic configuration of an optical coupling type semiconductor device according to Embodiment 7 of the present invention.

FIG. 8 is a see-through side view that shows the schematic configuration of a conventional semiconductor device.

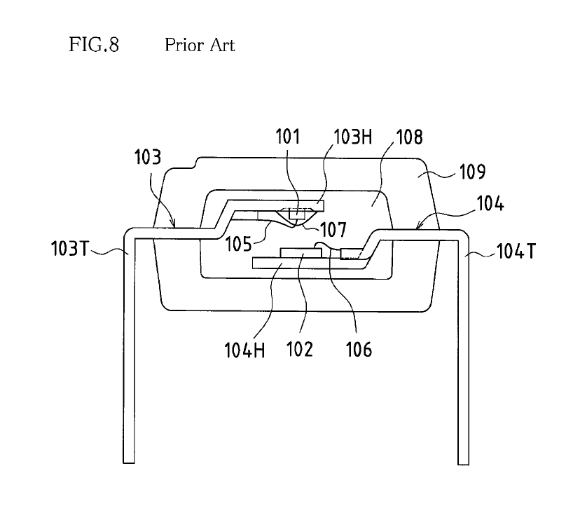

FIG. 9 is a flow chart that illustrates general production steps of the conventional semiconductor device.

### DESCRIPTION OF THE PREFERRED EMBODIMENTS

Hereinafter, embodiments of the present invention will be described with reference to the accompanying drawings.

### Embodiment 1

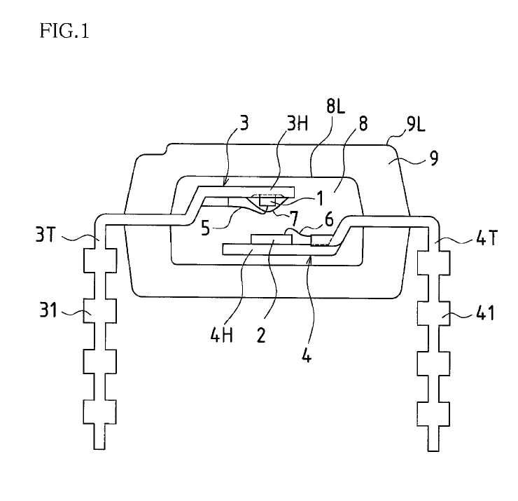

FIG. 1 is a see-through side view that shows the schematic configuration of an optical coupling type semiconductor device according to Embodiment 1 of the present invention.

A light emitting element 1 and a light receiving element 2 are mounted respectively to a header portion (light emitting side: 3H and light receiving side: 4H) of separate lead frames (light emitting side lead frame 3 and light receiving side lead frame 4). The light emitting element 1 and the light receiving element 2 are wire bonded with a wire (light emitting side wire 5 and light receiving side wire 6) such as gold wire. Also, a silicone resin 7 is applied to the light emitting element 1 as a pre-coat.

The light emitting element 1 and the light receiving element 2 are disposed so that they optically face each other, and the elements (the light emitting element 1 and the light receiving element 2) are sealed with resin sealing members (primary resin sealing member 8 and secondary resin sealing member 9). More specifically, the entirety of the light emitting element 1, the light receiving element 2, and the header portions 3H and 4H of the lead frames 3 and 4 are sealed with the primary resin sealing member 8 formed with translucent resin, and furthermore an outer circumference face 8L of the primary resin sealing member 8 is entirely coated with the secondary resin sealing member 9 formed with light intercepting resin.

Led-out portions (light emitting side: 3T and light receiving side: 4T) of the lead frames 3 and 4 that are led out from side faces of the secondary resin sealing member 9 have a plurality of protrusion portions (light emitting side: 31 and light receiving side: 41) formed thereon. In other words, a structure is adopted in which heat dissipation properties are improved by increasing the surface area of the lead frames 3 and 4 through formation of a plurality of the protrusion portions 31 and 41.

Thus, heat generation during power on is mitigated and since the package size can be reduced or when the same package size is kept, the current capacity can be increased, it is possible to achieve a small-sized optical coupling type semiconductor device with a current capacity larger than that of a conventional optical coupling type semiconductor device.

Also, the protrusion portions 31 and 41 are formed on the led-out portions 3T and 4T so as to have a structure that makes it possible to temporarily secure with the protrusion portions 31 and 41 when mounting on a mounting substrate is performed.

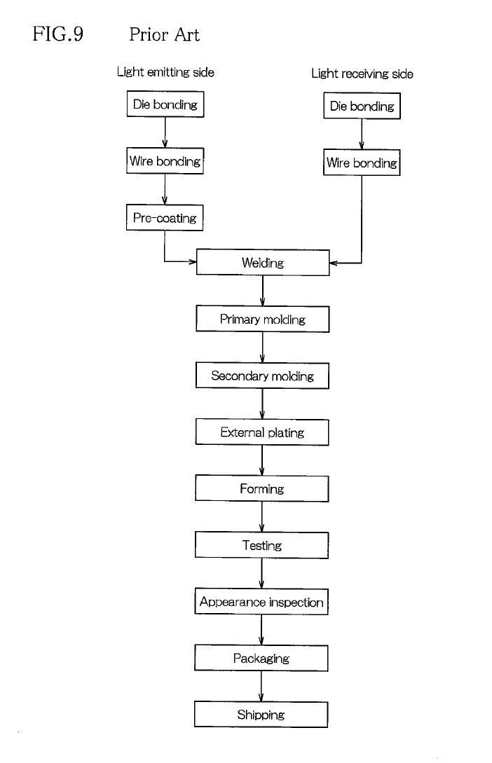

In addition, the optical coupling type semiconductor device according to this embodiment is produced in almost the same production steps (see FIG. 9) as that of a conventional optical coupling type semiconductor device. In other words, the optical coupling type semiconductor device according to this embodiment is formed by performing a step of mounting the light emitting element 1 and the light receiving element 2 respectively to the separate lead frames (light emitting side lead frame 3 and light receiving side lead frame 4) (die bonding step and wire bonding step), a step of sealing the light emitting element and the light receiving element with resin (primary molding step and secondary molding step), and others.

However, in the method for producing the optical coupling type semiconductor device according to this embodiment, a step of forming a plurality of the protrusion portions (light emitting side: 31 and light receiving side: 41) on the lead frames (light emitting side lead frame 3 and light receiving side lead frame 4) is provided, and thereby an optical coupling type semiconductor device with good heat dissipation properties can be produced.

If a step of forming the protrusion portions 31 and 41 on the lead frames 3 and 4 is performed prior to a die bonding step, a production method similar to conventional production methods can be used in and after the die bonding step to facilitate production.

Also, the protrusion portions 31 and 41 can be formed by breaking or bending a part of the lead frames through press work.

### Embodiment 2

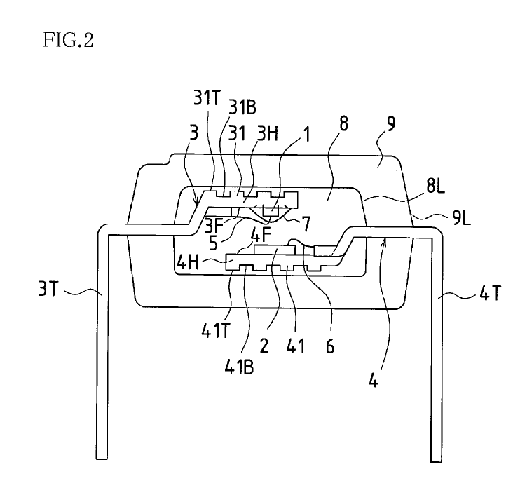

FIG. 2 is a see-through side view that shows the schematic configuration of an optical coupling type semiconductor device according to Embodiment 2 of the present invention.

Since the basic configuration of the optical coupling type semiconductor device according to this embodiment is similar to the configuration of the optical coupling type semiconductor device according to Embodiment 1, the points different from the optical coupling type semiconductor device according to Embodiment 1 will be hereinafter described.

In the optical coupling type semiconductor device according to this embodiment, protrusion portions (light emitting side: 31 and light receiving side 41) are formed on a face opposite to a mounting face (light emitting side: 3F and light receiving side: 4F) on which a light emitting element 1 or a light receiving element 2 of header portions (light emitting side: 3H and light receiving side: 4H) of lead frames (light emitting side lead frame 3 and light receiving side lead frame 4) is mounted.

In other words, the protrusion portions 31 and 41 that can improve heat dissipation by increasing the surface area of the lead frames 3 and 4 are formed not on led-out portions (light emitting side: 3T and light receiving side: 4T) but on the header portions 3H and 4H that are to be enclosed in a resin sealing member (primary resin sealing member 8) so that substrate mounting can be performed using a method similar to that of the conventional technology.

### Embodiment 3

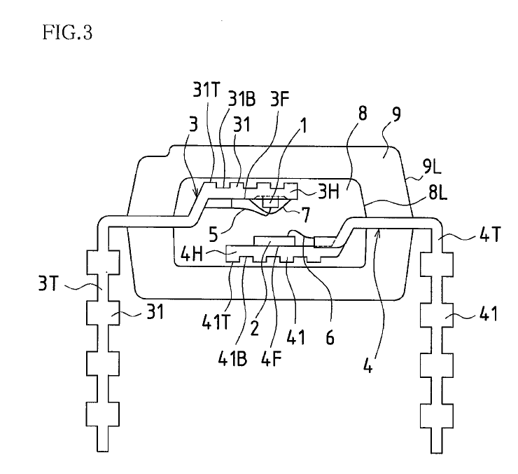

FIG. 3 is a see-through side view that shows the schematic configuration of an optical coupling type semiconductor device according to Embodiment 3 of the present invention.

Since the basic configuration of the optical coupling type semiconductor device according to this embodiment is similar to the configuration of the optical coupling type semiconductor device according to Embodiments 1 and 2, the points different from the optical coupling type semiconductor device according to Embodiments 1 and 2 will be hereinafter described.

In the optical coupling type semiconductor device according to this embodiment, protrusion portions (light emitting side: 31 and light receiving side: 41) are formed on both led-out portions (light emitting side: 3T and light receiving side: 4T) of lead frames (light emitting side lead frame 3 and light receiving side lead frame 4) and head portions (light emitting side: 3H and light receiving side: 4H). The protrusion portions 31 and 41 of the header portions 3H and 4H are formed on a face opposite to a mounting face (light emitting side: 3F and light receiving side 4F) on which a light emitting element 1 or a light receiving element 2 is mounted.

In other words, since the protrusion portions 31 and 41 are formed on the header portions 3H and 4H as well as on the led-out portions 3T and 4T, the surface area of the lead frames 3 and 4 is larger than that of the optical coupling type semiconductor device according to Embodiments 1 and 2 of the same package size, and heat dissipation properties are further improved.

Thus, heat generation during power on is further mitigated, and since the package size can be further reduced or when the same package size is kept, the current capacity can be further increased, it is possible to achieve a small-sized optical coupling type semiconductor device with a current capacity further larger than a conventional optical coupling type semiconductor device.

### Embodiment 4

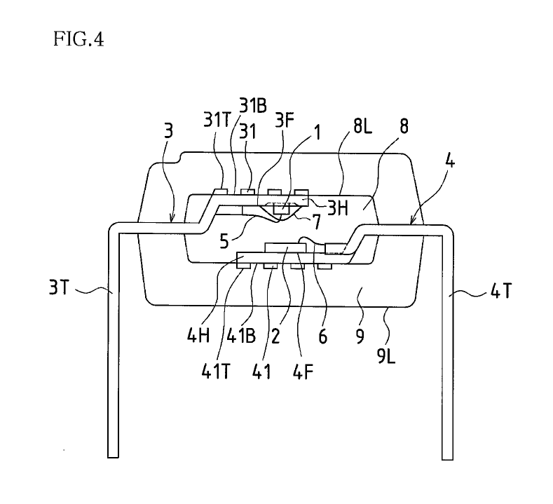

FIG. 4 is a see-through side view that shows the schematic configuration of an optical coupling type semiconductor device according to Embodiment 4 of the present invention.

Since the basic configuration of the optical coupling type semiconductor device according to this embodiment is similar to the configuration of the optical coupling type semiconductor device according to Embodiments 1 through 3, the points different from the optical coupling type semiconductor device according to Embodiments 1 through 3 will be hereinafter described.

In the optical coupling type semiconductor device according to this embodiment, protrusion portions (light emitting side: 31 and light receiving side: 41) are, similarly to the optical coupling type semiconductor device according to Embodiment 2 (see FIG. 2), formed on header portions (light emitting side: 3H and light receiving side: 4H) of lead frames (light emitting side lead frame 3 and light receiving side lead frame 4). In other words, the protrusion portions 31 and 41 are formed on a face opposite to a mounting face (light emitting side: 3F and light receiving side 4F) on which a light emitting element 1 or a light receiving element 2 is mounted.

However, unlike the optical coupling type semiconductor device according to Embodiment 2, bottom faces of the protrusion portions 31 and 41 (light emitting side: 31B and light receiving side: 41B) are in contact with an outer circumference face 8L of a primary resin sealing member 8 so that the protrusions 31 and 41 are enclosed in a secondary resin sealing member 9. The bottom faces 31B and 41B of the protrusion portions 31 and 41 are portions that do not have the protrusion portions 31 or 41 formed thereon and that match the outer circumference face of the lead frames 3 and 4.

In other words, compared to the optical coupling type semiconductor device according to Embodiment 2 of the same package size, the distance between the top faces of the protrusion portions 31 and 41 (light emitting side: 31T and light receiving side: 41T) and an outer circumference face 9L of the secondary resin sealing member 9 is shorter, and this structure facilitates dissipation of the heat generated during power on to the outside of the secondary resin sealing member 9. That is to say, the optical coupling type semiconductor device according to this embodiment has better heat dissipation properties than the optical coupling type semiconductor device according to Embodiment 2 of the same package size.

Similar to the optical coupling type semiconductor device according to Embodiment 3 (see FIG. 3), it is also possible to further improve heat dissipation properties by providing the protrusion portions 31 and 41 on led-out portions 3T and 4T of the lead frames 3 and 4 as well.

### Embodiment 5

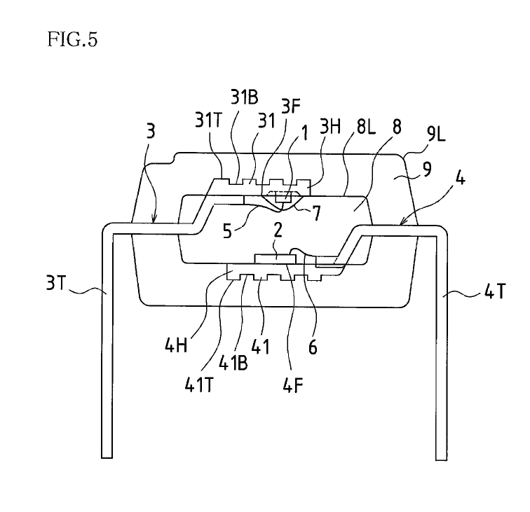

FIG. 5 is a see-through side view that shows the schematic configuration of an optical coupling type semiconductor device according to Embodiment 5 of the present invention.

Since the basic configuration of the optical coupling type semiconductor device according to this embodiment is similar to the configuration of the optical coupling type semiconductor device according to Embodiments 1 through 4, the points different from the optical coupling type semiconductor device according to Embodiments 1 through 4 will be hereinafter described.

In the optical coupling type semiconductor device according to this embodiment, protrusion portions (light emitting side: 31 and light receiving side: 41) are, similarly to the optical coupling type semiconductor device according to Embodiments 2 and 4 (see FIGS. 2 and 4), formed on header portions (light emitting side: 3H and light receiving side: 4H) of lead frames (light emitting side lead frame 3 and light receiving side lead frame 4). In other words, the protrusion portions 31 and 41 are formed on a face opposite to a mounting face (light emitting side: 3F and light receiving side 4F) on which a light emitting element 1 or a light receiving element 2 is mounted.

However, unlike Embodiments 2 and 4, the mounting faces 3F and 4F of the head portions 3H and 4H are in contact with an outer circumference face 8L of a primary resin sealing member 8, and the header portions 3H and 4H are enclosed in a secondary resin sealing member 9.

In other words, compared to the optical coupling type semiconductor device according to Embodiment 4 of the same package size, the distance between top faces 31T and 41T of the protrusion portions 31 and 41 and an outer circumference face 9L of the secondary resin sealing member 9 is still shorter, and this structure further facilitates dissipation of the heat generated during power on to the outside of the secondary resin sealing member 9. That is, the optical coupling type semiconductor device according to this embodiment has still better heat dissipation properties than the optical coupling type semiconductor device according to Embodiment 4 of the same package size.

Similar to the optical coupling type semiconductor device according to Embodiment 3 (see FIG. 3), it is also possible to further improve heat dissipation properties by providing the protrusion portions 31 and 41 on led-out portions 3T and 4T of the lead frames 3 and 4 as well.

### Embodiment 6

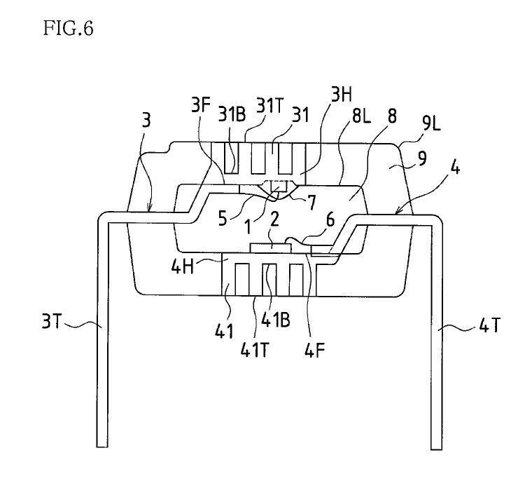

FIG. 6 is a see-through side view that shows the schematic configuration of an optical coupling type semiconductor device according to Embodiment 6 of the present invention.

Since the basic configuration of the optical coupling type semiconductor device according to this embodiment is similar to the configuration of the optical coupling type semiconductor device according to Embodiments 1 through 5, the points different from the optical coupling type semiconductor device according to Embodiments 1 through 5 will be hereinafter described.

In the optical coupling type semiconductor device according to this embodiment, protrusion portions (light emitting side: 31 and light receiving side: 41) are, similarly to the optical coupling type semiconductor device according to Embodiments 2, 4, and 5 (see FIGS. 2, 4, and 5), formed on header portions (light emitting side: 3H and light receiving side: 4H) of lead frames (light emitting side lead frame 3 and light receiving side lead frame 4). In other words, the protrusion portions 31 and 41 are formed on a face opposite to a mounting face (light emitting side: 3F and light receiving side 4F) on which a light emitting element 1 or a light receiving element 2 is mounted.

Also, similar to the optical coupling type semiconductor device according to Embodiment 5 (see FIG. 5), the mounting faces 3F and 4F of the header portions 3H and 4H are in contact with an outer circumference face 8L of a primary resin sealing member 8.

In addition, according to this embodiment, top faces (light emitting side: 31T and light receiving side: 41T) of the protrusion portions 31 and 41 are in contact with an outer circumference face 9L of a secondary resin sealing member 9. In other words, the optical coupling type semiconductor device according to this embodiment has a structure in which top faces 31T and 41T of the protrusion portions 31 and 41 are exposed to the outside of the secondary resin sealing member 9, and compared to the optical coupling type semiconductor device according to Embodiment 5 of the same package size, this structure further facilitates dissipation of the heat generated during power on to the outside of the secondary resin sealing member 9. In other words, the optical coupling type semiconductor device according to this embodiment has still better heat dissipation properties than the optical coupling type semiconductor device according to Embodiment 5 of the same package size.

The optical coupling type semiconductor device according to this embodiment has, as mentioned above, a structure in which the mounting faces 3F and 4F of the header portions 3H and 4H are in contact with the outer circumference face 8L of the primary resin sealing member 8, but even in an optical coupling type semiconductor device that has a structure in which, like the optical coupling type semiconductor device according to Embodiment 4 (see FIG. 4), bottom faces 31B and 41B of the protrusion portions 31 and 41 are in contact with the outer circumference face 8L of the primary resin sealing member 8 and furthermore top faces 31T and 41T of the protrusion portions 31 and 41 are in contact with the outer circumference face 9L of the secondary resin sealing member 9, effects similar to that of the optical coupling type semiconductor device according to this embodiment can be achieved since the top faces 31T and 41T of the protrusion portions 31 and 41 are exposed to the outside of the secondary resin sealing member 9.

Also, similar to the optical coupling type semiconductor device according to Embodiment 3 (see FIG. 3), it is also possible to further improve heat dissipation properties by providing the protrusion portions 31 and 41 on led-out portions 3T and 4T of the lead frames 3 and 4 as well.

### Embodiment 7

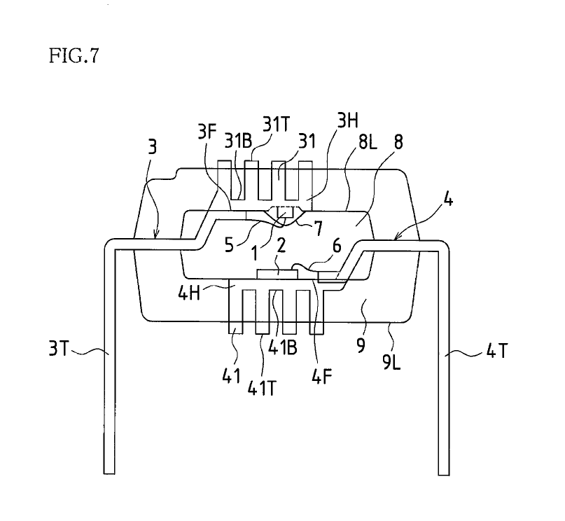

FIG. 7 is a see-through side view that shows the schematic configuration of an optical coupling type semiconductor device according to Embodiment 7 of the present invention.

Since the basic configuration of the optical coupling type semiconductor device according to this embodiment is similar to the configuration of the optical coupling type semiconductor device according to Embodiments 1 through 6, the points different from the optical coupling type semiconductor device according to Embodiments 1 through 6 will be hereinafter described.

In the optical coupling type semiconductor device according to this embodiment, protrusion portions (light emitting side: 31 and light receiving side: 41) are, similarly to the optical coupling type semiconductor device according to Embodiments 2 and 4 through 6 (see FIGS. 2 and 4 through 6), formed on header portions (light emitting side: 3H and light receiving side: 4H) of lead frames (light emitting side lead frame 3 and light receiving side lead frame 4). In other words, the protrusion portions 31 and 41 are formed on a face opposite to a mounting face (light emitting side: 3F and light receiving side 4F) on which a light emitting element 1 or a light receiving element 2 is mounted.

Also, similar to the optical coupling type semiconductor device according to Embodiments 5 and 6 (see FIGS. 5 and 6), the mounting faces 3F and 4F of the header portions 3H and 4H are in contact with an outer circumference face 8L of a primary resin sealing member 8.

In addition, top faces 31T and 41T of the protrusion portions 31 and 41 extrude from an outer circumference face 9L of a secondary resin sealing member 9. In other words, the optical coupling type semiconductor device according to this embodiment has a structure in which the top faces 31T and 41T of the protrusion portions 31 and 41 protrude from the secondary resin sealing member 9, and compared to the optical coupling type semiconductor device according to Embodiment 6 of the same package size, this structure further facilitates dissipation of the heat generated during power on to the outside of the secondary resin sealing member 9. That is, the optical coupling type semiconductor device according to this embodiment has still better heat dissipation properties than the optical coupling type semiconductor device according to Embodiment 6 of the same package size.

The optical coupling type semiconductor device according to this embodiment has, as mentioned above, a structure in which the mounting faces 3F and 4F of the header portions 3H and 4H are in contact with an outer circumference face 8L of a primary resin sealing member 8, but even in an optical coupling type semiconductor device that has a structure in which, like the optical coupling type semiconductor device according to Embodiment 4 (see FIG. 4), bottom faces 31B and 41B of the protrusion portions 31 and 41 are in contact with the outer circumference face 8L of the primary resin sealing member 8 and furthermore the top faces 31T and 41T of the protrusion portions 31 and 41 protrude from the outer circumference face 9L of the secondary resin sealing member 9, effects similar to that of the optical coupling type semiconductor device according to this embodiment can be achieved since the top faces 31T and 41T of the protrusion portions (light emitting side: 31 and light receiving side: 41) protrude from the secondary resin sealing member 9.

Also, similar to the optical coupling type semiconductor device according to Embodiment 3 (see FIG. 3), it is also possible to further improve heat dissipation properties by providing the protrusion portions 31 and 41 on led-out portions 3T and 4T of the lead frames 3 and 4 as well.

### Embodiment 8

An electronic device according to this embodiment (not shown) is an electronic device on which the optical coupling type semiconductor device according to any one of Embodiments 1 through 7 has been mounted. Since the electronic device has a small-sized optical coupling type semiconductor device with good heat dissipation properties mounted thereon, it is possible to achieve a highly safe small-sized electronic device.

Large effects can be obtained if used in an electronic device in which it is necessary to increase the current capacity, such as power equipment, office automation equipment, home electric appliance and factory automation equipment, or when an electronic device requires product size reduction while maintaining the current capacity.

The present invention may be embodied in various other forms without departing from the spirit or essential characteristics thereof. The embodiments disclosed in this application are to be considered in all respects as illustrative and not limiting. The scope of the invention is indicated by the appended claims rather than by the foregoing description, and all modifications or changes that come within the meaning and range of equivalency of the claims are intended to be embraced therein.

1. An optical coupling type semiconductor device comprising lead frames on which a light emitting element and a light receiving element have been respectively separately mounted and a resin sealing member that seals the light emitting element and the light receiving element wherein a plurality of protrusion portions are formed on the lead frames.

2. The optical coupling type semiconductor device according to claim 1, wherein the protrusion portions are formed on led-out portions of the lead frames that are led out from side faces of the resin sealing member.

3. The optical coupling type semiconductor device according to claim 1, wherein the protrusion portions are formed on a face opposite to a mounting face on which the light emitting element or the light receiving element of header portions of the lead frames, having been sealed with the resin sealing member, has been mounted.

4. The optical coupling type semiconductor device according to claim 3, wherein the resin sealing member comprises a primary resin sealing member that covers the light emitting element and the light receiving element and a secondary resin sealing member that covers an outer circumference of the primary resin sealing member, and w
herein bottom faces of the protrusion portions are in contact with the outer circumference face of the primary resin sealing member.

5. The optical coupling type semiconductor device according to claim 3, wherein the resin sealing member comprises a primary resin sealing member that covers the light emitting element and the light receiving element and a secondary resin sealing member that covers an outer circumference of the primary resin sealing member, and wherein the mounting faces of the header portions are in contact with the outer circumference face of the primary resin sealing member.

6. The optical coupling type semiconductor device according to claim 4, wherein top faces of the protrusion portions are in contact with the outer circumference face of the secondary resin sealing member.

7. The optical coupling type semiconductor device according to claim 4, wherein top faces of the protrusion portions protrude from the outer circumference face of the secondary resin sealing member.

8. A method for producing an optical coupling type semiconductor device comprising a step of mounting a light emitting element and a light receiving element to respective separate lead frames and a step of sealing the light emitting element and the light receiving element with resin, the method for producing the optical coupling type semiconductor device comprising a step of forming a plurality of protrusion portions on the lead frames.

9. An electronic device on which an optical coupling type semiconductor device according to claim 1, has been mounted.

10. The optical coupling type semiconductor device according to claim 2, wherein the protrusion portions are formed on a face opposite to a mounting face on which the light emitting element or the light receiving element of header portions of the lead frames, having been sealed with the resin sealing member, has been mounted.

11. The optical coupling type semiconductor device according to claim 5, wherein top faces of the protrusion portions are in contact with the outer circumference face of the secondary resin sealing member.

12. The optical coupling type semiconductor device according to claim 5, wherein top faces of the protrusion portions protrude from the outer circumference face of the secondary resin sealing member.

13. An electronic device on which an optical coupling type semiconductor device according to claim 2, has been mounted.

14. An electronic device on which an optical coupling type semiconductor device according to claim 3, has been mounted.

15. An electronic device on which an optical coupling type semiconductor device according to claim 4, has been mounted.

16. An electronic device on which an optical coupling type semiconductor device according to claim 5, has been mounted.

17. An electronic device on which an optical coupling type semiconductor device according to claim 6, has been mounted.

18. An electronic device on which an optical coupling type semiconductor device according to claim 7, has been mounted.
